(19) United States
(12) Patent Application Publication
(10) Pub. No.: US 2013/0160828 A1
(43) Pub. Date: Jun. 27, 2013

(54) THIN-FILM SOLAR CELL

(71) Applicants: CHEN-WEI PENG, Miaoli County (TW); CHAO-HSIUNG HUANG, Taichung City (TW); YAO-CHUNG TSAO, Kaohsiung City (TW)

(72) Inventors: CHEN-WEI PENG, Miaoli County (TW); CHAO-HSIUNG HUANG, Taichung City (TW); YAO-CHUNG TSAO, Kaohsiung City (TW)

(21) Appl. No.: 13/427,567

(22) Filed: Mar. 22, 2012

(30) Foreign Application Priority Data
Dec. 27, 2011 (TW) 100149033

(51) Int. Cl. H01L 31/0224; H01L 31/0376

(52) U.S. Cl. 136/255; 136/258

(57) ABSTRACT

The present invention discloses a thin-film solar cell, which comprises an electrode layer and a semiconductor layer. The semiconductor layer comprises a P-type layer, an I-type layer and an N-type layer. The P-type layer is disposed on the electrode layer. The I-type layer comprises an I-type amorphous silicon layer and an I-type polymorphous silicon layer. The I-type amorphous silicon layer is disposed on the P-type layer. The I-type polymorphous silicon layer is disposed on the I-type amorphous silicon layer. The N-type layer is disposed on the I-type polymorphous silicon layer. Wherein, the I-type polymorphous silicon layer generates a crystalline diffraction event and reduces photolysis reaction for enhancing the conversion efficiency of the thin-film solar cell.

### CROSS-REFERENCE TO RELATED APPLICATION

This application claims the benefit of Taiwan Patent Application No. 100149033, filed on Dec. 27, 2011, in the Taiwan Intellectual Property Office, the disclosure of which is incorporated herein in its entirety by reference.

### BACKGROUND OF THE INVENTION

1. Field of the Invention

The present invention relates to a thin-film solar cell, and more particularly to the thin-film solar cell that changes the material of an I-type layer in a semiconductor layer of a conventional thin-film solar cell to enhance the conversion efficiency of the solar cell efficiently.

2. Description of Related Art

In recent years, people pay increasingly more attention to environmental protection, and energy sources become gradually exhausted, so that substitute energies including solar energy become more important. Solar energy is a natural inexhaustive energy that can avoid the issue of its being monopolized. Since solar cells have the advantages of convenient use, pollution free, and long lifespan, solar cells can be used as a good energy source.

At present, a general solar cell comprises a thin-film solar cell with the advantages of a lower cost, a smaller thickness and a lower power loss. In present existing technologies, the basic manufacturing process of a conventional thin-film solar cell 1 mainly adopts a three-layer structured P-I-N semiconductor layer 12, wherein the semiconductor layer 12 comprises a P-type layer 121, an I-type layer 122 and an N-type layer 123, and the P-type layer 121, I-type layer 122 and N-type layer 123 of the semiconductor layer 12 are formed sequentially on an electrode layer 11 by a sputtering method or a chemical vapor deposition method as shown in FIG. 1. In the prior art, intrinsic silicon thin films are mainly composed of hydrogen atoms and silicon atoms. In normal conditions, hydrogen atoms and silicon atoms exist in form of amorphous silicon (a-Si), and disorderly arranged lights may decline the conversion efficiency of the thin-film solar cell easily.

Although the technology of thin-film solar cell tends to be well-developed now, improvements are required since the conversion efficiency of the thin-film solar cell is still not high enough to meet user requirements.

### SUMMARY OF THE INVENTION

In view of the aforementioned problems of the prior art, it is a primary objective of the invention to provide a thin-film solar cell to overcome the problems of the conventional thin-film solar cell with the low conversion efficiency.

To achieve the foregoing objective, the present invention provides a thin-film solar cell comprising an electrode layer and a semiconductor layer. The semiconductor layer comprises a P-type layer, an I-type layer and an N-type layer. The P-type layer is disposed on the electrode layer. The I-type layer comprises an I-type amorphous silicon layer and an I-type polymorphous silicon layer, wherein the I-type amorphous silicon layer is disposed on the P-type layer, the I-type polymorphous silicon layer is disposed on the I-type amorphous silicon layer, and the N-type layer is disposed on the I-type polymorphous silicon layer. Wherein, the I-type amorphous silicon layer has a thickness percentage with respect to the thickness of the I-type layer greater than that of the I-type polymorphous silicon layer.

Preferably, the thin-film solar cell of the present invention further comprises a substrate, and the electrode layer is disposed on the substrate.

Preferably, the substrate is made of metal or opaque glass.

Preferably, the electrode layer is a transparent conductive thin film formed by fluorine-doped tin dioxide or boron-doped zinc oxide.

Preferably, the I-type amorphous silicon layer has a thickness of 2300 angstroms.

Preferably, the I-type polymorphous silicon layer has a thickness of 200 angstroms.

Preferably, the I-type amorphous silicon layer has a thickness equal to 92% of the thickness of the I-type layer, and I-type polymorphous silicon layer has a thickness equal to 8% of the thickness of the I-type layer.

Preferably, the thickness percentage of the I-type polymorphous silicon layer with respect to the thickness of the I-type layer can be adjusted to 9%˜92%, and the thickness percentage of the I-type amorphous silicon layer with respect to the thickness of the I-type layer can be adjusted to 91%˜8% correspondingly.

Preferably, the polymorphous silicon layer is formed on the I-type layer by changing an arrangement of hydrogen atoms and silicon atoms in the I-type layer to adjust a process parameter of a plasma-enhanced chemical vapor deposition (PECVD) process, and the adjustment of the process parameter includes adjusting a pressure above 80 pa and a temperature below 200° C.

Preferably, the amorphous silicon layer and the polymorphous silicon layer in the I-type layer is distinguished by a diffraction pattern of the I-type layer photographed from a transmission electron microscope (TEM).

To achieve the foregoing objective, the present invention further provides a thin-film solar cell comprising an electrode layer and a semiconductor layer. The semiconductor layer comprises a P-type layer, an I-type layer and a N-type layer. The P-type layer is disposed on the electrode layer. The I-type layer comprises an I-type amorphous silicon layer and an I-type polymorphous silicon layer, wherein the I-type amorphous silicon layer is disposed on the P-type layer, the I-type polymorphous silicon layer is disposed on the I-type amorphous silicon layer, and the N-type layer is disposed on the I-type polymorphous silicon layer. The I-type amorphous silicon layer has a thickness percentage with respect to the I-type layer smaller than that of the I-type polymorphous silicon layer.

Preferably, I-type amorphous silicon layer has a thickness of 200 angstroms.

Preferably, I-type polymorphous silicon layer has a thickness of 2300 angstroms.

Preferably, the I-type amorphous silicon layer has a thickness equal to 8% of the thickness of the I-type layer, and I-type polymorphous silicon layer has a thickness equal to 92% of the thickness of the I-type layer.

Preferably, the thickness percentage of the I-type polymorphous silicon layer with respect to the thickness of the I-type layer is adjusted to 91%˜8%, and the thickness percentage of the I-type amorphous silicon layer with respect to the thickness of the I-type layer is adjusted to 9%˜92% accordingly.

To achieve the foregoing objective, the present invention further provides a thin-film solar cell comprising an electrode layer and a semiconductor layer. The semiconductor layer comprises a P-type layer, an I-type layer and an N-type layer. The P-type layer is disposed on the electrode layer. The I-type layer comprises an I-type polymorphous silicon layer and an I-type amorphous silicon layer, wherein the I-type polymorphous silicon layer is disposed on the P-type layer, the I-type amorphous silicon layer is disposed on the I-type polymorphous silicon layer, and the N-type layer is disposed on the I-type amorphous silicon layer. Wherein, the thickness percentage of I-type amorphous silicon layer with respect to the thickness of the I-type layer greater than that of the I-type polymorphous silicon layer.

Preferably, the I-type amorphous silicon layer has a thickness of 2300 angstroms.

Preferably, the I-type polymorphous silicon layer has a thickness of 200 angstroms.

Preferably, the I-type amorphous silicon layer has a thickness equal to 92% of the thickness of the I-type layer, and I-type polymorphous silicon layer has a thickness equal to 8% of the thickness of the I-type layer.

Preferably, the thickness percentage of the I-type polymorphous silicon layer with respect to the thickness of the I-type layer is adjusted to 9%˜92%, and the thickness percentage of the I-type amorphous silicon layer with respect to the thickness of the I-type layer is adjusted to 91%˜8% accordingly.

To achieve the foregoing objective, the present invention further provides a thin-film solar cell comprising an electrode layer and a semiconductor layer. The semiconductor layer comprises a P-type layer, an I-type layer and an N-type layer. The P-type layer is disposed on the electrode layer. The I-type layer comprises an I-type polymorphous silicon layer and an I-type amorphous silicon layer, wherein the I-type polymorphous silicon layer is disposed on the P-type layer, the I-type amorphous silicon layer is disposed on the I-type polymorphous silicon layer, and the N-type layer is disposed on the I-type amorphous silicon layer. Wherein, the thickness percentage of I-type amorphous silicon layer with respect to the thickness of the I-type layer is smaller than that of the I-type polymorphous silicon layer.

Preferably, the I-type amorphous silicon layer has a thickness of 200 angstroms.

Preferably, the I-type polymorphous silicon layer has a thickness of 2300 angstroms.

Preferably, the thickness of the I-type amorphous silicon layer is equal to 8% of the I-type layer, and the thickness of I-type polymorphous silicon layer is equal to 92% of the I-type layer.

Preferably, the thickness percentage of the I-type polymorphous silicon layer with respect to the thickness of the I-type layer is further adjusted to 91%˜8%, and the thickness percentage of the I-type amorphous silicon layer is adjusted to 9%˜92% accordingly.

In the thin-film solar cell of the present invention, parameters of a plasma-enhanced chemical vapor deposition (PECVD) process can be adjusted to form the polymorphous silicon (pm-Si), wherein the present invention uses a material to mix two crystalline silicon layers with different bandgaps to change the I-type layer in the semiconductor layer, and the amorphous silicon layer and the polymorphous silicon layer are mixed to achieve the bandgap engineering. The properties of the polymorphous silicon (pm-Si) having a bandgap and an open-circuit voltage greater than those of amorphous silicon (a-Si) to enhance the transmission of electron holes, so as to reduce a photolysis reaction to achieve a higher conversion efficiency of the thin-film solar cell.

The technical contents and characteristics of the present invention will become apparent with the detailed description of a preferred embodiment accompanied with related drawings as follows.

### BRIEF DESCRIPTION OF THE DRAWINGS

FIG. 1 is a schematic view of a conventional thin-film solar cell;

FIG. 2 is a schematic view of a thin-film solar cell in accordance with a first preferred embodiment of the present invention;

FIG. 3 is a data chart comparing the properties of materials for making an I-type amorphous silicon layer and an I-type polymorphous silicon layer of a thin-film solar cell of the present invention;

FIGS. 4A-4D are graphs comparing the conversion efficiency (Eff), open-circuit voltage (Voc), short-circuit density (Jsc) and fill factor of a thin-film solar cell of the present invention with those of a conventional I-type layer;

FIG. 5 is a graph showing the conversion efficiency after light is projected onto an I-type amorphous silicon layer and an I-type polymorphous silicon layer of a thin-film solar cell of the present invention;

FIG. 6 is a schematic view of a thin-film solar cell in accordance with a second preferred embodiment of the present invention;

FIG. 7 is a schematic view of a thin-film solar cell in accordance with a third preferred embodiment of the present invention;

FIG. 8 is a schematic view of a thin-film solar cell in accordance with a fourth preferred embodiment of the present invention;

FIG. 9 are photos comparing diffraction patterns of a polymorphous silicon layer, an amorphous silicon layer and a micro-chip silicon layer micro-chip silicon layer of a thin-film solar cell of the present invention; and

FIG. 10 is a data chart analyzing the bandgaps (Eg) of an I-type amorphous silicon layer and an I-type polymorphous silicon layer of a thin-film solar cell of the present invention.

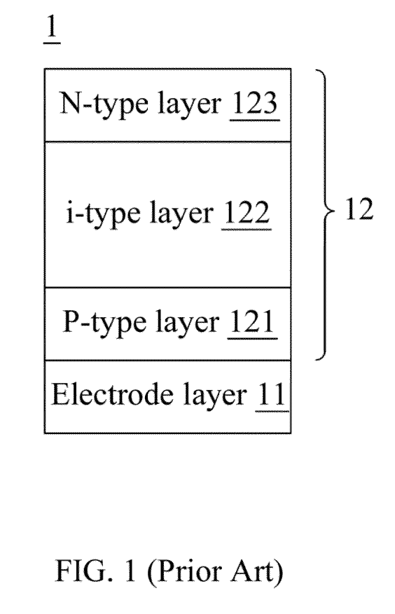

### DETAILED DESCRIPTION OF THE PREFERRED EMBODIMENTS

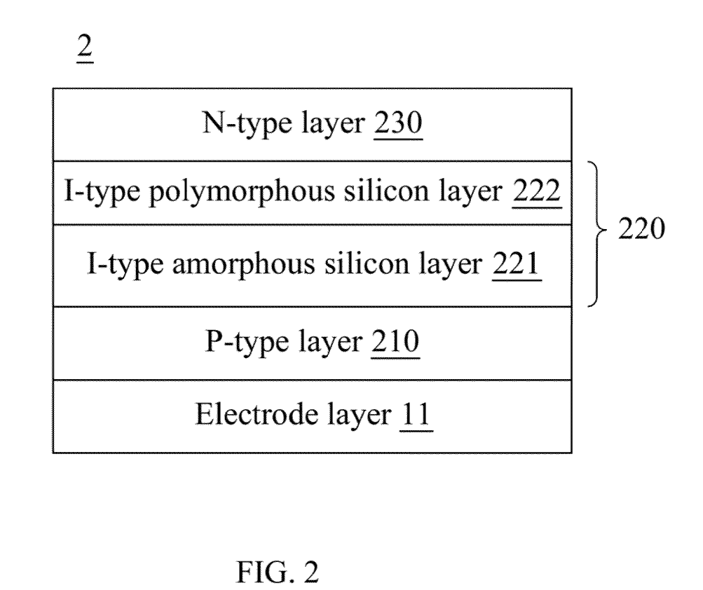

With reference to FIG. 2 for a schematic view of a thin-film solar cell in accordance with the first preferred embodiment of the present invention, the thin-film solar cell 2 comprises an electrode layer 200, a P-type layer 210, an I-type layer 220 and an N-type layer 230, wherein the P-type layer 210, I-type layer 220 and N-type layer 230 are semiconductor layers. The thin-film solar cell 2 further comprises a substrate (not shown in the figure) formed by of metal or opaque glass. The electrode layer 200 is disposed on the substrate, and can be a transparent conductive thin film made of fluorine-doped tin dioxide or boron-doped zinc oxide. The P-type layer 210 is disposed on the electrode layer 200. The I-type layer 220 is made of a material different from the conventional ones, and comprises an I-type amorphous silicon layer 221 and an I-type polymorphous silicon layer 222, wherein the amorphous silicon is not in a crystalline arrangement, so that the conversion efficiency may decline easily when being projected with light. The arrangement of polymorphous silicon may fall between the single-crystalline silicon and the amorphous silicon to produce diffractions, such that the silicon crystals are arranged sequentially to reduce the photolysis reaction. The I-type amorphous silicon layer 221 is disposed on the P-type layer 210, and the I-type polymorphous silicon layer 222 is disposed on the I-type amorphous silicon layer 221, and the I-type amorphous silicon layer 221 preferably has a thickness of 2300 angstroms, and the I-type polymorphous silicon layer 222 preferably has a thickness of 200 angstroms, but the invention is not limited to such arrangement only. The N-type layer 230 is disposed on the I-type polymorphous silicon layer 222.

In the first preferred embodiment, the thickness of the I-type amorphous silicon layer 221 of the thin-film solar cell 2 is equal to 92% of the thickness of the I-type layer 220, and the thickness of the I-type polymorphous silicon layer 222 is equal to 8% of the thickness of the I-type layer 220, and the thickness percentage of the I-type polymorphous silicon layer 222 with respect to the thickness of the I-type layer 220 can be adjusted to 9%˜92%, and the thickness percentage of the I-type amorphous silicon layer 221 with respect to the thickness of the I-type layer can be adjusted to 91%˜8% accordingly.

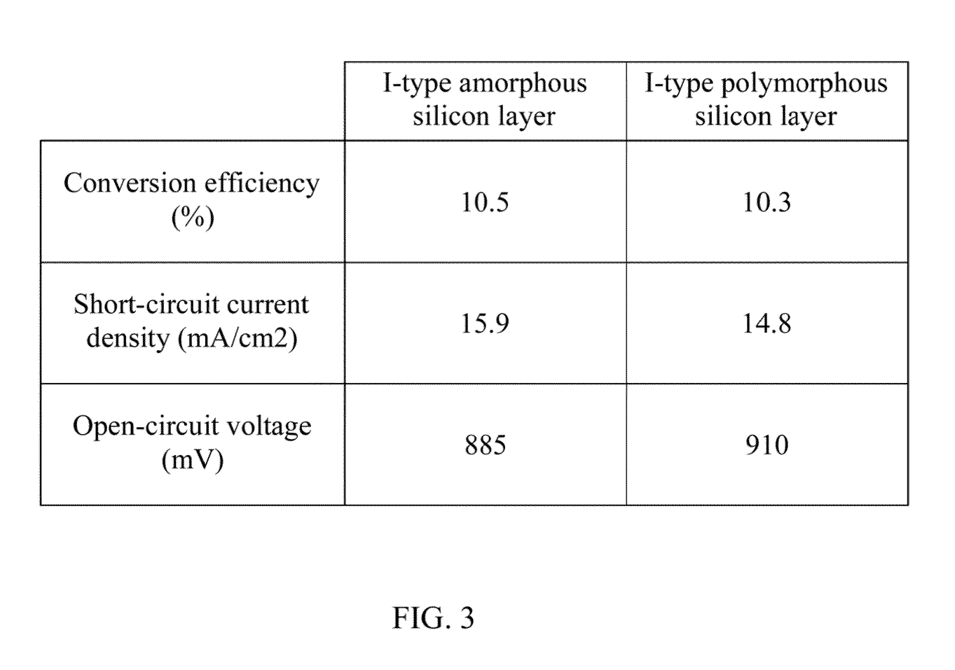

In general, three values including a fill factor (FF), an open-circuit voltage (Voc) and a short-circuit current density (Jsc) are taken into consideration for measuring the conversion efficiency (Eff), and these three values are positively correlated to the conversion efficiency. Compared with the conventional thin-film solar cells, the thin-film solar cell 2 of the present invention has higher conversion efficiency as shown in FIGS. 3 to 5.

With reference to FIG. 3 for a data chart comparing the properties of materials for making an I-type amorphous silicon layer and an I-type polymorphous silicon layer of a thin-film solar cell of the present invention, the I-type amorphous silicon layer 221 and the I-type polymorphous silicon layer 222 have a conversion efficiency (Eff) equal to 10.5% and 10.3% respectively to maintain a stable status. In addition, the I-type amorphous silicon layer 221 and the I-type polymorphous silicon layer 222 have a short-circuit current density (Jsc) equal to 15.9 mA/cm2 and 14.8 mA/cm2 respectively to maintain a stable status; and the I-type amorphous silicon layer 221 and the I-type polymorphous silicon layer 222 have an open-circuit voltage (Voc) equal to 885 mV and 910 mV respectively. Obviously, the I-type polymorphous silicon layer 222 of the thin-film solar cell 2 of the present invention can increase the open-circuit voltage (Voc), so that the I-type polymorphous silicon layer 222 has the properties of low current and high voltage to produce a larger bandgap and extend the flow of electric current increase, so as to improve the conversion efficiency of the thin-film solar cell.

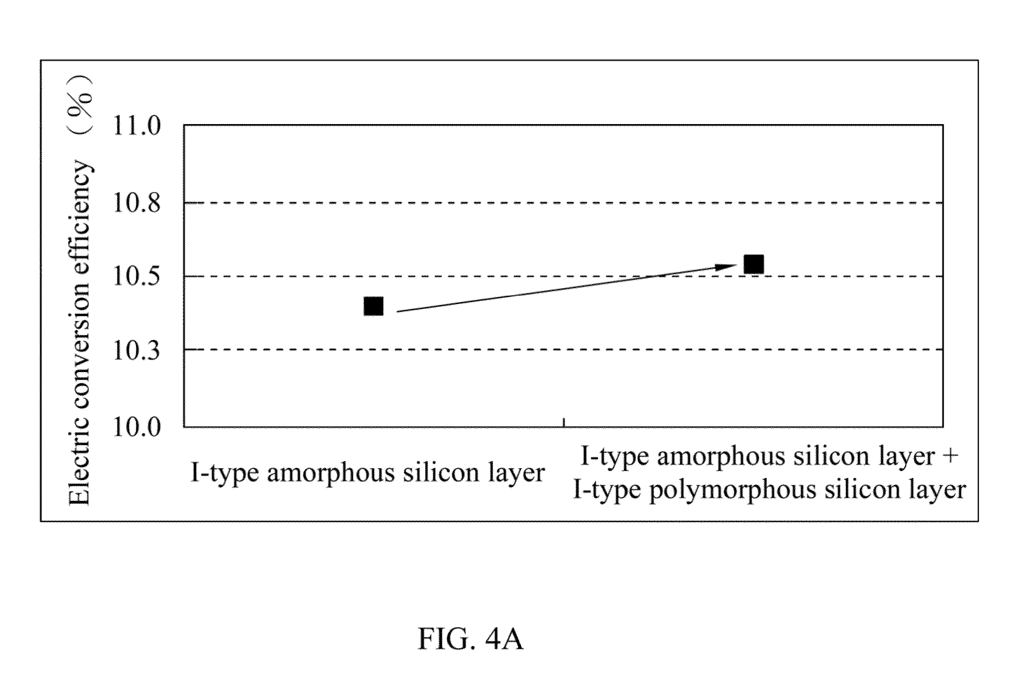

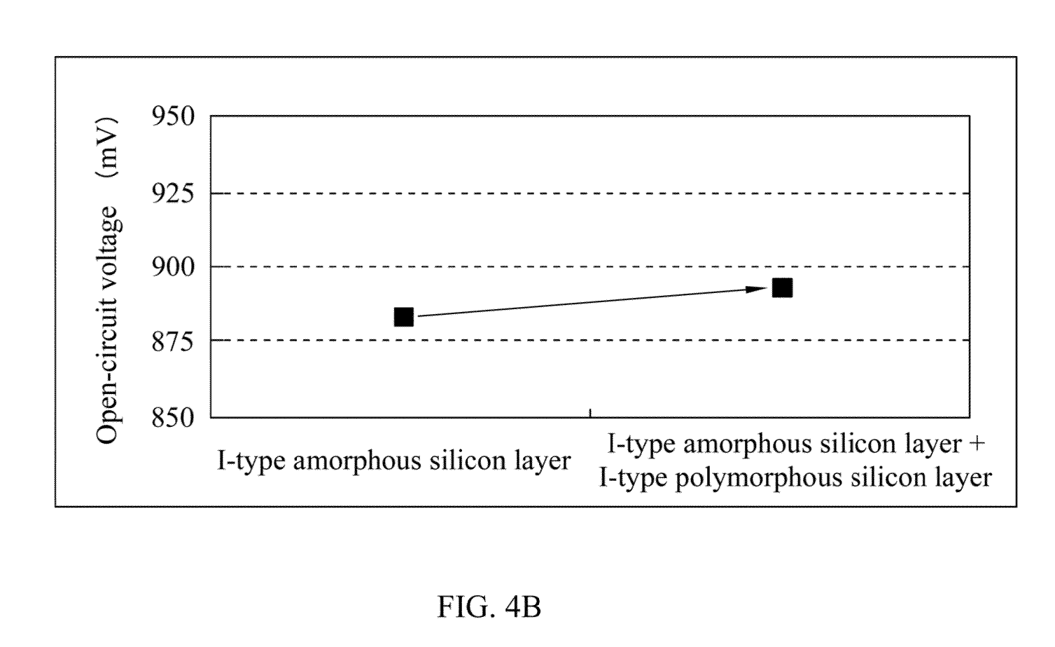

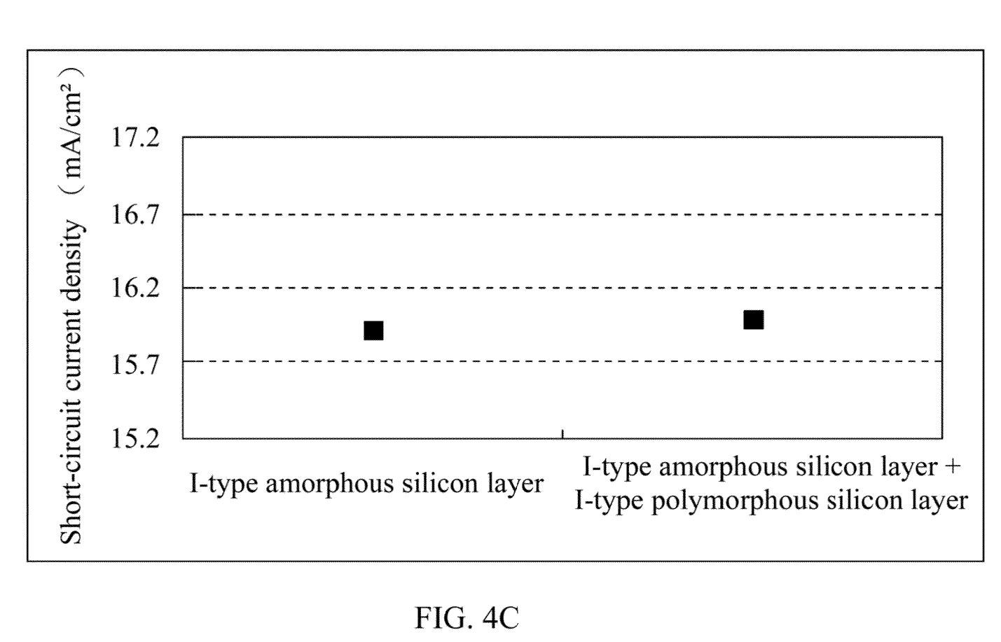

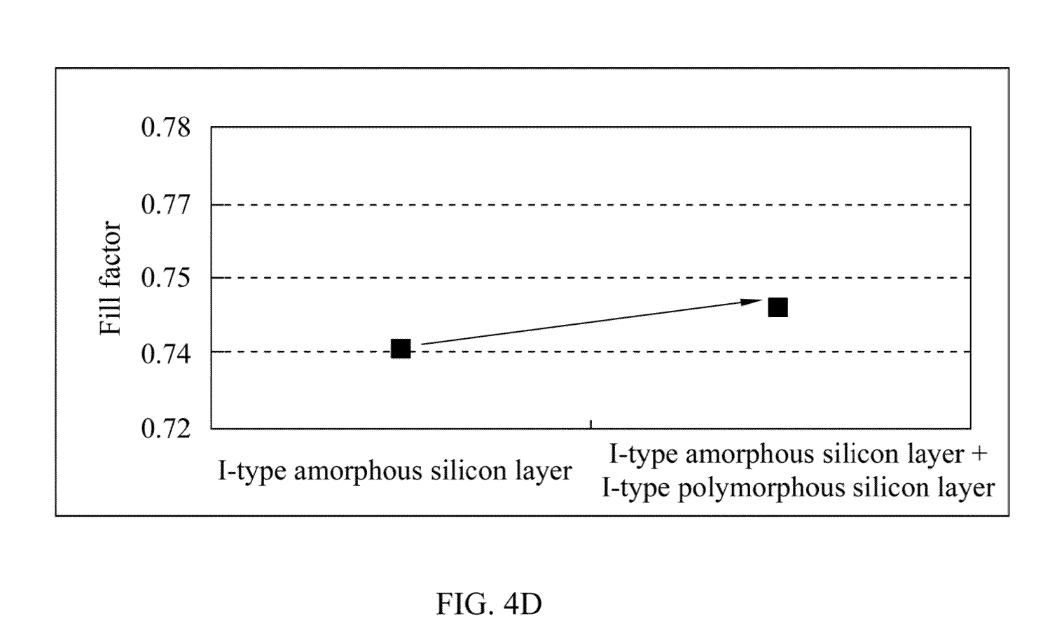

With reference to FIGS. 4A-4D for graphs comparing the conversion efficiency (Eff), open-circuit voltage (Voc), short-circuit density (Jsc) and fill factor of a thin-film solar cell of the present invention with those of a conventional I-type layer, the I-type layer 220 of the thin-film solar cell 2 of the present invention is made of mixed materials of the I-type amorphous silicon layer 221 and the I-type polymorphous silicon layer 222 to obtain a light conversion efficiency (Eff), an open-circuit voltage (Voc), a short-circuit current density (Jsc) and a fill factor (FF) better than those of the conventional thin-film solar cell 1. It shows that a separate use of the I-type amorphous silicon layer 221 or the I-type polymorphous silicon layer 222 can achieve a lower conversion efficiency than a mixed use of the I-type amorphous silicon layer 221 and the I-type polymorphous silicon layer 222, thus further showing that the thin-film solar cell 2 of the present invention can improve the conversion efficiency.

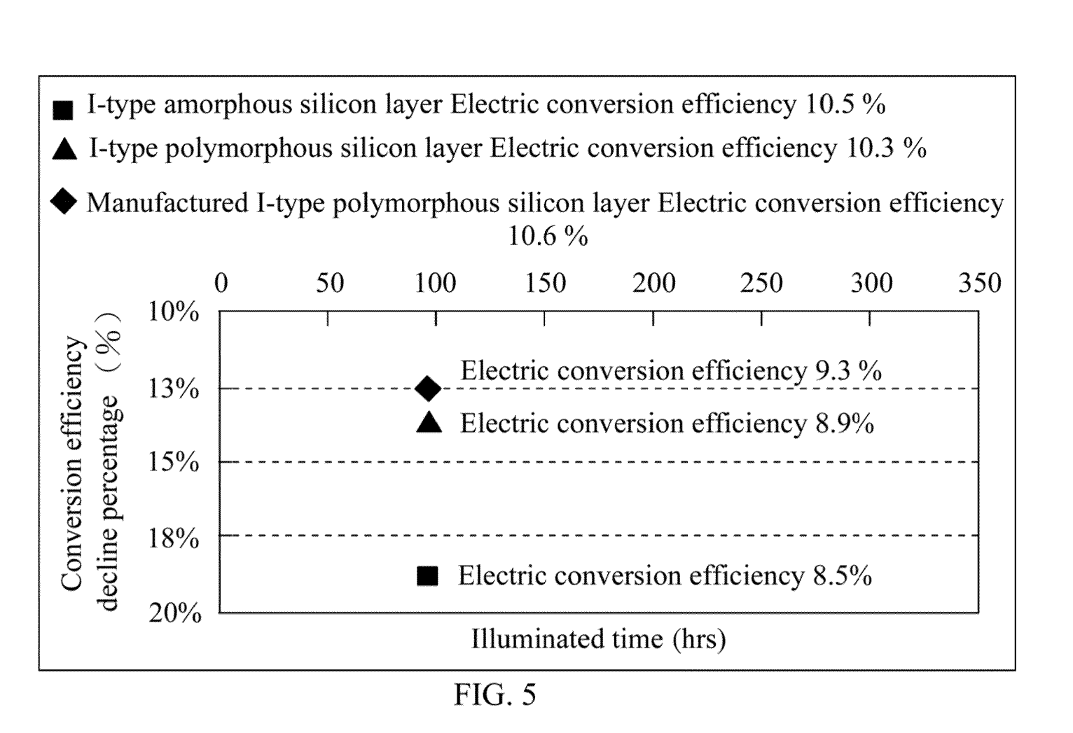

With reference to FIG. 5 for a graph showing the conversion efficiency of an I-type amorphous silicon layer and an I-type polymorphous silicon layer of a thin-film solar cell of the present invention after being illuminated, the I-type amorphous silicon layer 221 has a conversion efficiency (Eff) of 10.5%, and the I-type polymorphous silicon layer 222 has a conversion efficiency (Eff) of 10.3%, and their mixed layer has a conversion efficiency (Eff) of 10.6% before the material of the I-type layer 220 of the thin-film solar cell 2 of the present invention is illuminated, After being illuminated for 96 hours, the I-type amorphous silicon layer 221 has a conversion efficiency (Eff) dropped to 8.5%; the I-type polymorphous silicon layer 222 has a conversion efficiency (Eff) dropped to 8.9%, and the mixed layer has a conversion efficiency (Eff) dropped to 9.3%. Therefore, the I-type amorphous silicon layer 221 and the I-type polymorphous silicon layer 222 are mixed, and the bandgap engineering is adopted to enhance the transmission of electron holes and reduce the photolysis reaction, thus showing that the thin-film solar cell 2 of the present invention can improve the conversion efficiency.

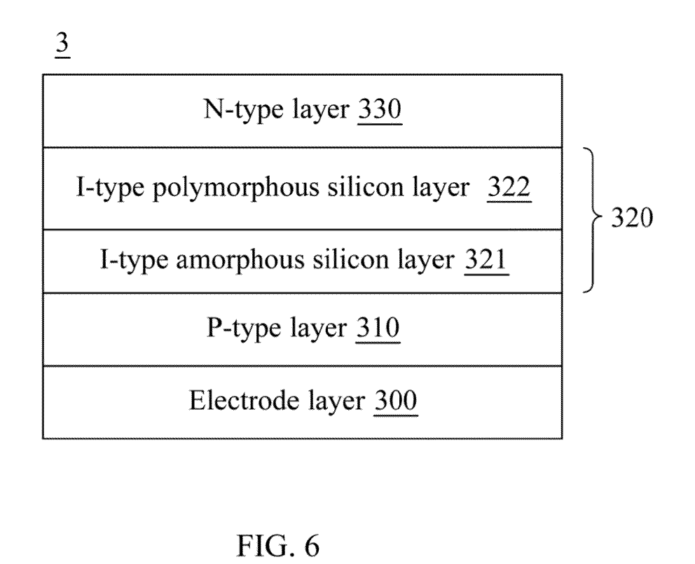

With reference to FIG. 6 a schematic view of a thin-film solar cell in accordance with the second preferred embodiment of the present invention, the thin-film solar cell 3 comprises an electrode layer 300, a P-type layer 310, an I-type layer 320 and an N-type layer 330, and the P-type layer 310, I-type layer 320 and N-type layer 330 are semiconductor layers, and the thin-film solar cell 3 further comprises a substrate (not shown in the figure). The electrode layer 300 is disposed on the substrate. The P-type layer 310 is disposed on the electrode layer 300. The I-type layer 320 includes an I-type amorphous silicon layer 321 and an I-type polymorphous silicon layer 322, wherein the I-type amorphous silicon layer 321 is disposed on the P-type layer 310, the I-type polymorphous silicon layer 322 is disposed on the I-type amorphous silicon layer 321, and the N-type layer 330 is disposed on the I-type polymorphous silicon layer 322. The I-type amorphous silicon layer 321 preferably has a thickness of 200 angstroms or equal to 8% of the thickness of the I-type layer 320, the I-type polymorphous silicon layer 322 preferably has a thickness of 2300 angstroms or equal to 92% of the thickness of the I-type layer 320. The thickness percentage of the I-type polymorphous silicon layer 322 with respect to the thickness of the I-type layer 320 can be adjusted to 91%˜8%, and the thickness percentage of the I-type amorphous silicon layer 321 is adjusted to 9%˜92% accordingly. However, the invention is not limited to such arrangement only.

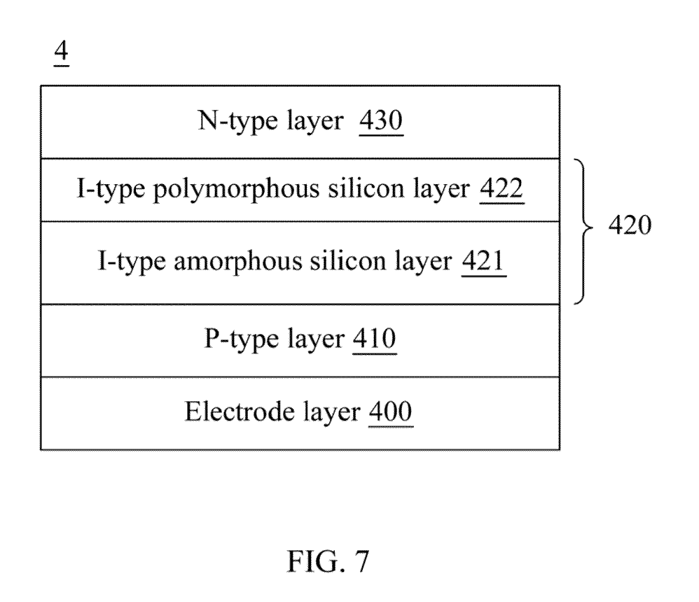

With reference to FIG. 7 for a schematic view of a thin-film solar cell in accordance with the third preferred embodiment of the present invention, the thin-film solar cell 4 comprises an electrode layer 400 and a semiconductor layer, and the semiconductor layer comprises a P-type layer 410, an I-type layer 420 and an N-type layer 430. The thin-film solar cell 4 further comprises a substrate (not shown in the figure). The electrode layer 400 is disposed on the substrate. The P-type layer 410 is disposed on the electrode layer 400. The I-type layer 420 comprises an I-type polymorphous silicon layer 421 and an I-type amorphous silicon layer 422, wherein I-type polymorphous silicon layer 421 is disposed on the P-type layer 410, and the I-type amorphous silicon layer 422 is disposed on the I-type polymorphous silicon layer 421. The I-type amorphous silicon layer 421 has a thickness of 2300 angstroms or equal to 92% of the thickness of the I-type layer 420. The I-type polymorphous silicon layer 421 has a thickness of 200 angstroms or equal to 8% of the I-type layer 420. Further, the thickness percentage of the I-type polymorphous silicon layer 421 with respect to the thickness of the I-type layer 420 can be adjusted to 9%˜92%, and the thickness percentage of the I-type amorphous silicon layer 422 can be adjusted to 91%˜8% accordingly. The N-type layer 430 is disposed on the I-type amorphous silicon layer 422.

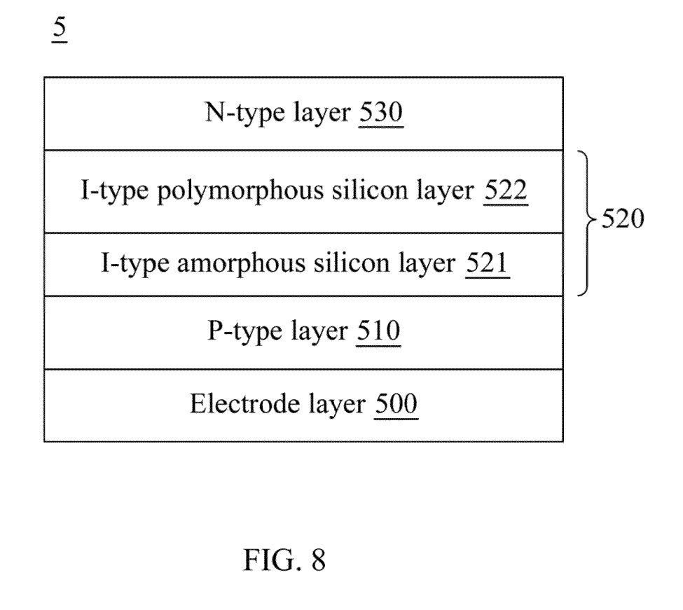

With reference to FIG. 8 for a schematic view of a thin-film solar cell in accordance with the fourth preferred embodiment of the present invention, the thin-film solar cell 5 comprises an electrode layer 500, a P-type layer 510, an I-type layer 520 and an N-type layer 530, and the P-type layer 510, I-type layer 520 and N-type layer 530 are semiconductor layers. The thin-film solar cell 5 further comprises a substrate (not shown in the figure). The electrode layer 500 is disposed on the substrate, and the P-type layer 510 is disposed on the electrode layer 500. The I-type layer 520 comprises an I-type polymorphous silicon layer 521 and an I-type amorphous silicon layer 522. The I-type amorphous silicon layer 522 preferably has a thickness of 200 angstroms or equal to 8% of the thickness of the I-type layer 520, and the I-type polymorphous silicon layer 521 preferably has a thickness of 2300 angstroms or equal to 92% of the thickness of the I-type layer 520. The I-type polymorphous silicon layer 521 is disposed on the P-type layer 510, the I-type amorphous silicon layer 522 is disposed on the I-type polymorphous silicon layer 521, and the N-type layer 530 is disposed on the I-type amorphous silicon layer 522. Wherein, the thickness percentage of the I-type polymorphous silicon layer 521 with respect to the thickness of I-type layer 520 can be further adjusted to 91%˜8%, and the thickness percentage of the I-type amorphous silicon layer 522 can be adjusted to 9%˜92% accordingly. However, the invention is not limited to such arrangement only.

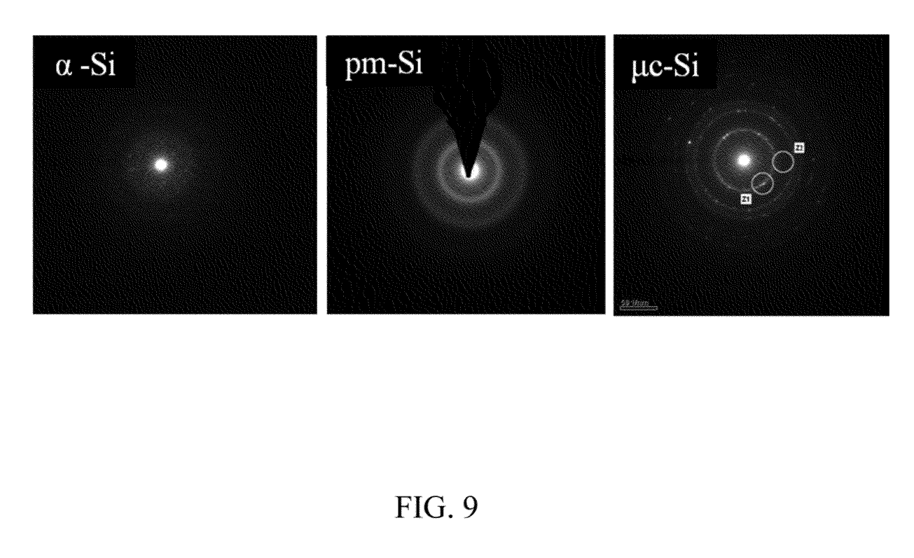

In the present invention, parameters of a plasma-enhanced chemical vapor deposition (PECVD) are adjusted to form polymorphous silicon (pm-Si). In the process, a high voltage (>80 pa) is used to increase the chance of having collisions among silicon atoms, and a low temperature (<200° C.) is used to decrease the chance of forming dusts of the polymorphous silicon by high temperature. However, it is very difficult to distinguish the crystalline arrangements of the polymorphous silicon and the amorphous silicon, so that diffraction patterns are used for analyzing the crystalline arrangement, wherein the principle of the diffraction for identifying the silicon crystals by passing electron beams through the constructive diffraction pattern generated by periodic arrays of atoms. In other words, each diffraction point represents the atomic plane of a crystalline structure. If molecules are arranged orderly, diffraction rings can be observed in the diffraction pattern, and a bright spot in each ring represents the constructive diffraction produced by the periodic arrangement of atoms. With reference to FIG. 9 for the photos arranged from left to right showing the diffraction patterns of an amorphous silicon (a-Si) layer, a polymorphous silicon (pm-Si) layer and a micro-chip silicon (μm-Si) layer of a thin-film solar cell of the present invention, the amorphous silicon (a-Si) atoms are not arranged orderly, and the diffraction ring is not obvious; the micro-chip silicon (μm-Si) atoms show obvious diffraction spots, and the polymorphous silicon (pm-Si) atoms have obvious diffraction spots but not as many as the micro-chip silicon (μm-Si) atoms which are arranged in a short-range order instead of the long-range order.

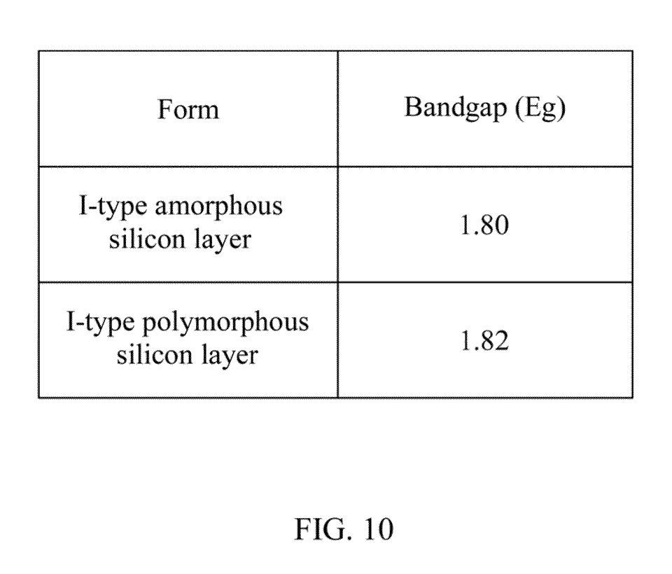

With reference to FIG. 10 for a data chart analyzing the bandgaps (Eg) of an I-type amorphous silicon layer and an I-type polymorphous silicon layer of a thin-film solar cell of the present invention, the amorphous silicon (a-Si) has a bandgap (Eg) of 1.80 eV, and the polymorphous silicon (pm-Si) has a bandgap (Eg) of 1.82 eV, wherein the present invention mixes crystalline silicon of two different bandgaps and uses the mixed silicon to form bandgap engineering and uses the properties of a larger bandgap of the polymorphous silicon (pm-Si) and an open-circuit voltage greater than the amorphous silicon (a-Si) such as 885 to 910 mV as shown in FIG. 3 to enhance the transmission of electron holes, so as to achieve the effects of enhancing the conversion efficiency, reducing the photolysis reaction, and providing a high efficiency of the solar cell.

In summation of the description above, the present invention mainly changes the material of the I-type layer in the semiconductor layer of the conventional thin-film solar cell and adjusts the parameters of the plasma-enhanced chemical vapor deposition (PECVD) process parameter to form polymorphous silicon (pm-Si), and further mixes the amorphous silicon layer with the polymorphous silicon layer to produce a crystalline diffraction of the polymorphous silicon to reduce the photolysis reaction, so as to enhance the conversion efficiency of the thin-film solar cell.

While the means of specific embodiments in present invention has been described by reference drawings, numerous modifications and variations could be made thereto by those skilled in the art without departing from the scope and spirit of the invention set forth in the claims. The modifications and variations should in a range limited by the specification of the present invention.

What is claimed is:

1. A thin-film solar cell, comprising:
an electrode layer; and
a semiconductor layer, comprising:
a P-type layer, disposed on the electrode layer;
an I-type layer, comprising an I-type amorphous silicon layer and an I-type polymorphous silicon layer, and the I-type amorphous silicon layer being disposed on the P-type layer, and the I-type polymorphous silicon layer being disposed on the I-type amorphous silicon layer; and
an N-type layer, disposed on the I-type polymorphous silicon layer;
wherein the I-type amorphous silicon layer has a thickness percentage with respect to the thickness of the I-type layer greater than that of the I-type polymorphous silicon layer.

2. The thin-film solar cell of claim 1, further comprising a substrate, and the electrode layer being disposed on the substrate.

3. The thin-film solar cell of claim 2, wherein the substrate is made of metal or opaque glass.

4. The thin-film solar cell of claim 1, wherein the electrode layer is a transparent conductive thin film formed by fluorine-doped tin dioxide or boron-doped zinc oxide.

5. The thin-film solar cell of claim 1, wherein the I-type amorphous silicon layer has a thickness of 2300 angstroms.

6. The thin-film solar cell of claim 1, wherein the I-type polymorphous silicon layer has a thickness of 200 angstroms.

7. The thin-film solar cell of claim 1, wherein the I-type amorphous silicon layer has a thickness equal to 92% of the thickness of the I-type layer, and the I-type polymorphous silicon layer has a thickness equal to 8% of the thickness of the I-type layer.

8. The thin-film solar cell of claim 7, wherein the thickness percentage of the I-type polymorphous silicon layer with respect to the thickness of the I-type layer is adjusted to 9%˜92%, and the thickness percentage of the I-type amorphous silicon layer with respect to the thickness of the I-type layer is relatively adjusted to 91%˜8%.

9. The thin-film solar cell of claim 1, wherein the polymorphous silicon layer is formed on the I-type layer by changing an arrangement of hydrogen atoms and silicon atoms in the I-type layer to adjust a process parameter of a plasma-enhanced chemical vapor deposition (PECVD) process, and the adjustment of the process parameter comprises adjusting a pressure above 80 pa and a temperature below 200° C.

10. The thin-film solar cell of claim 1, wherein the amorphous silicon layer and the polymorphous silicon layer in the I-type layer is distinguished by a diffraction pattern of the I-type layer photographed from a transmission electron microscope (TEM).

11. A thin-film solar cell, comprising:
an electrode layer; and
a semiconductor layer, comprising:
a P-type layer, disposed on the electrode layer;
an I-type layer, comprising an I-type amorphous silicon layer and an I-type polymorphous silicon layer, and the I-type amorphous silicon layer being disposed on the P-type layer, and the I-type polymorphous silicon layer being disposed on the I-type amorphous silicon layer; and
an N-type layer, disposed on the I-type polymorphous silicon layer;
wherein the I-type amorphous silicon layer has a thickness percentage with respect to the thickness of the I-type layer less than that of the I-type polymorphous silicon layer.

12. The thin-film solar cell of claim 11, further comprising a substrate, and the electrode layer being disposed on the substrate.

13. The thin-film solar cell of claim 12, wherein the substrate is made of metal or opaque glass.

14. The thin-film solar cell of claim 11, wherein the electrode layer is a transparent conductive thin film formed by fluorine-doped tin dioxide or boron-doped zinc oxide.

15. The thin-film solar cell of claim 11, wherein the I-type amorphous silicon layer has a thickness of 200 angstroms.

16. The thin-film solar cell of claim 11, wherein the I-type polymorphous silicon layer has a thickness of 2300 angstroms.

17. The thin-film solar cell of claim 11, wherein the I-type amorphous silicon layer has a thickness equal to 8% of the thickness of the I-type layer, and the I-type polymorphous silicon layer has a thickness equal to 92% of the thickness of the I-type layer.

18. The thin-film solar cell of claim 17, wherein the thickness percentage of the I-type polymorphous silicon layer with respect to the thickness of the I-type layer is adjusted to 91%˜8%, and the thickness percentage of the I-type amorphous silicon layer with respect to the thickness of the I-type layer is relatively adjusted to 9%˜92%.

19. A thin-film solar cell, comprising:
an electrode layer; and
a semiconductor layer, comprising:
a P-type layer, disposed on the electrode layer;
an I-type layer, comprising an I-type polymorphous silicon layer and an I-type amorphous silicon layer, and the I-type polymorphous silicon layer being disposed on the P-type layer, and the I-type amorphous silicon layer being disposed on the I-type polymorphous silicon layer; and
an N-type layer, disposed on the I-type amorphous silicon layer;
wherein, the I-type amorphous silicon layer has a thickness percentage with respect to the thickness of the I-type layer greater than that of the I-type polymorphous silicon layer.

20. The thin-film solar cell of claim 19, further comprising a substrate, and the electrode layer being disposed on the substrate.

21. The thin-film solar cell of claim 20, wherein the substrate is made of metal or opaque glass.

22. The thin-film solar cell of claim 19, wherein the electrode layer is a transparent conductive thin film formed by fluorine-doped tin dioxide or boron-doped zinc oxide.

23. The thin-film solar cell of claim 19, wherein the I-type amorphous silicon layer has a thickness of 2300 angstroms.

24. The thin-film solar cell of claim 19, wherein the I-type polymorphous silicon layer has a thickness of 200 angstroms.

25. The thin-film solar cell of claim 19, wherein the I-type amorphous silicon layer has a thickness equal to 92% of the thickness of the I-type layer, and the I-type polymorphous silicon layer has a thickness equal to 8% of the thickness of the I-type layer.

26. The thin-film solar cell of claim 25, wherein the thickness percentage of the I-type polymorphous silicon layer with respect to the thickness of the I-type layer is adjusted to 9%˜92%, and the thickness percentage of the I-type amorphous silicon layer with respect to the thickness of the I-type layer is relatively adjusted to 91%˜8%.

27. A thin-film solar cell, comprising:
an electrode layer; and
a semiconductor layer, comprising:
a P-type layer, disposed on the electrode layer;
an I-type layer, comprising an I-type polymorphous silicon layer and an I-type amorphous silicon layer, and the I-type polymorphous silicon layer being disposed on the P-type layer, and the I-type amorphous silicon layer being disposed on the I-type polymorphous silicon layer; and
an N-type layer, disposed on the I-type amorphous silicon layer;
wherein, the I-type amorphous silicon layer has a thickness percentage with respect to the thickness of the I-type layer less than that of the I-type polymorphous silicon layer.

28. The thin-film solar cell of claim 27, further comprising a substrate, and the electrode layer being disposed on the substrate.

29. The thin-film solar cell of claim 28, wherein the substrate is made of metal or opaque glass.

30. The thin-film solar cell of claim 27, wherein the electrode layer is a transparent conductive thin film formed by fluorine-doped tin dioxide or boron-doped zinc oxide.

31. The thin-film solar cell of claim 27, wherein the I-type amorphous silicon layer has a thickness of 200 angstroms.

32. The thin-film solar cell of claim 27, wherein the I-type polymorphous silicon layer has a thickness of 2300 angstroms.

33. The thin-film solar cell of claim 27, wherein the I-type amorphous silicon layer has a thickness equal to 8% of the thickness of the I-type layer, and the I-type polymorphous silicon layer has a thickness equal to 92% of the thickness of the I-type layer.

34. The thin-film solar cell of claim 33, wherein the thickness percentage of the I-type polymorphous silicon layer with respect to the thickness of the I-type layer is adjusted to 91%˜8%, and the thickness percentage of the I-type amorphous silicon layer with respect to the thickness of the I-type layer is relatively adjusted to 9%˜92%.
